(19) United States
(12) Patent Application Publication
(10) Pub. No.: US 2021/0197543 A1
(43) Pub. Date: Jul. 1, 2021

(54) DETACHMENT DEVICE

(71) Applicant: SHINKAWA LTD., Tokyo (JP)

(72) Inventors: Hiromi SHIBAHARA, Tokyo (JP); Tomonori NAKAMURA, Tokyo (JP); Kohei SEYAMA, Tokyo (JP)

(73) Assignee: SHINKAWA LTD., Tokyo (JP)

(21) Appl. No.: 16/087,086

(22) PCT Filed: Mar. 23, 2017
(86) PCT No.: PCT/JP2017/011674

§ 371 Date: Dec. 3, 2018

(30) Foreign Application Priority Data
Mar. 23, 2016 (JP) 2016-058221

(51) Int. Cl. B32B 43/00; B65H 41/00

(52) U.S. Cl. CPC B32B 43/006; B65H 41/00

(57) ABSTRACT

This detachment device is provided with: a collet including a contact surface that comes into surface contact with a surface of a protective film adhering to an adhesion member attached on a workpiece, and including a suction hole that is provided in the contact surface and that sucks the protective film; and a movement mechanism that moves the collet relative to the workpiece, wherein while the protective film is being sucked by the suction hole, the collet is separated from the workpiece so that the protective film is detached from the adhesion member. Accordingly, the detachment device capable of more assuredly detaching the protective film from the workpiece is provided.

### TECHNICAL FIELD

The present specification discloses a detachment device that detaches a protective film protecting a surface of an adhesion member from the adhesion member attached to a workpiece.

### BACKGROUND ART

In recent years, miniaturization and increase in accuracy of electronic workpieces such as semiconductor elements have progressed to deal with high functionality and expansion to mobile applications of battery equipment. Since even slight contamination on a surface of a workpiece or the like may cause a problem in this case, there have been cases in which surfaces of workpieces are protected by protective films immediately before their use in recent years. In particular, when an adhesion member, for example, a DAF, is attached to a workpiece, a surface of the adhesion member may be protected by a protective film.

A semiconductor device is manufactured by, for example, attaching a semiconductor chip to a lead frame or a substrate using a die attach agent such as a liquid epoxy adhesive in a die bonding step. However, there are problems that, in a case of a small chip for mobile devices, it is difficult to apply an adhesive in an appropriate amount, and thus the adhesive may run over from the chip, and conversely in a case of a large chip for large capacity applications, an amount of an adhesive may be insufficient, which may bring about insufficient adhesive power.

In order to solve the problems, attaching an adhesive film that functions as a die attach agent (an adhesive) or an adhesion member that is a so-called die attach film (DAF) to a semiconductor chip in advance, instead of a liquid die attach agent, has been proposed. A protective film is attached to a surface of the DAF to protect the adhesion layer, and when the semiconductor chip covered with the DAF is to be used, the protective film peels off for use.

### CITATION LIST

### Patent Literature

[Patent Literature 1] Japanese Unexamined Patent Application Publication No. 2008-96530

[Patent Literature 2] Japanese Unexamined Patent Application Publication No. 2001-199624

### SUMMARY OF INVENTION

### Technical Problem

As a detachment method for protective films, a method of using an adhesive tape has been widely employed in the past. Patent Literature 1, for example, discloses a method of detaching a protective film by bringing an adhesive tape wound on a roller in contact with the protective film and separating the adhesive tape from a workpiece. When such an adhesive tape is used, however, there is concern of the adhesive tape contaminating a substrate or a workpiece.

Patent Literature 2 discloses a technology of detaching a protective film without using an adhesive tape. In Patent Literature 2, a protective film is sucked using a roll with a suction hole, the roll is rotated, and thereby the protective film is detached from a workpiece. However, when a member that detaches a protective film is set to a roll member as in Patent Literature 2, the roll member and the protective film can come in contact with each other only linearly. In addition, in order to prevent a leak in suction when the roll member is brought in contact with the protective film, the suction hole needs to be set as a small hole having a size that can fit in the linear contact portion. As a result, the power of the entire roll member to hold the protective film tends to become small, and thus the protective film may be inappropriately detached.

Therefore, the present specification discloses a detachment device that can detach a protective film from an adhesion member attached to a workpiece more reliably.

### Solution to Problem

A detachment device disclosed in the present specification is a detachment device that detaches a protective film protecting a surface of an adhesion member from the adhesion member attached to a workpiece, and the detachment device includes: a collet, including an contact surface that comes in contact with a surface of the protective film adhered to the adhesion member in a planar shape, and a suction hole that is provided within the contact surface and sucks the protective film; and a movement mechanism that moves the collet with respect to the workpiece, wherein the protective film is detached from the adhesion member by separating the collet from the workpiece in a state in which the protective film is sucked by the suction hole.

The contact surface may be tilted toward a surface of the workpiece, such that an inner end of the contact surface is set to be lower than an outer end of the contact surface in a range in which a leak during a suction does not occur.

In addition, the suction unit may suck a periphery of an end side of the protective film.

In addition, an area of the contact surface may be smaller than the protective film. In this case, the contact surface may come in contact with a periphery of an end of the protective film. In addition, in this case, the contact surface may come in contact with a periphery of an end of the protective film in a direction substantially orthogonal to a transport direction of the workpiece.

### Advantageous Effects of Invention

According to the detachment device disclosed in the present specification, the contact surface comes in contact with the protective film in a planar shape, and the suction hole is provided within the contact surface. Thus, a shape, a size, and the number of suction holes can be set relatively freely, and a desired suction power is easily obtained. As a result, the protective film can be detached more reliably.

### BRIEF DESCRIPTION OF DRAWINGS

FIG. 1 is a diagram illustrating a configuration of a detachment device for a protective film of the invention.

FIG. 2 is a schematic diagram illustrating shapes of a collet and workpieces.

FIG. 3 is a side view illustrating a state of detachment of the protective film.

FIG. 4 is an enlarged diagram of a part of FIG. 3.

FIG. 5 is a schematic diagram illustrating shapes of another collet and workpiece.

FIG. 6A is a schematic diagram illustrating a configuration of another collet and workpiece.

FIG. 6B is a schematic diagram illustrating a configuration of another collet and workpiece.

FIG. 7A is a schematic diagram illustrating a configuration of a conventional detachment device.

FIG. 7B is a diagram of the cross-section A-A of FIG. 7A.

### DESCRIPTION OF EMBODIMENTS

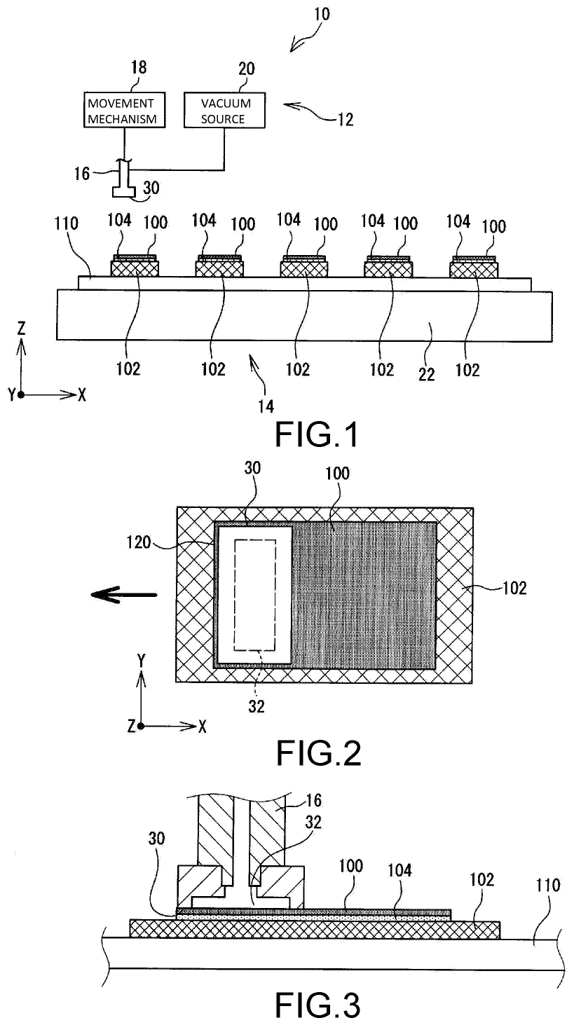

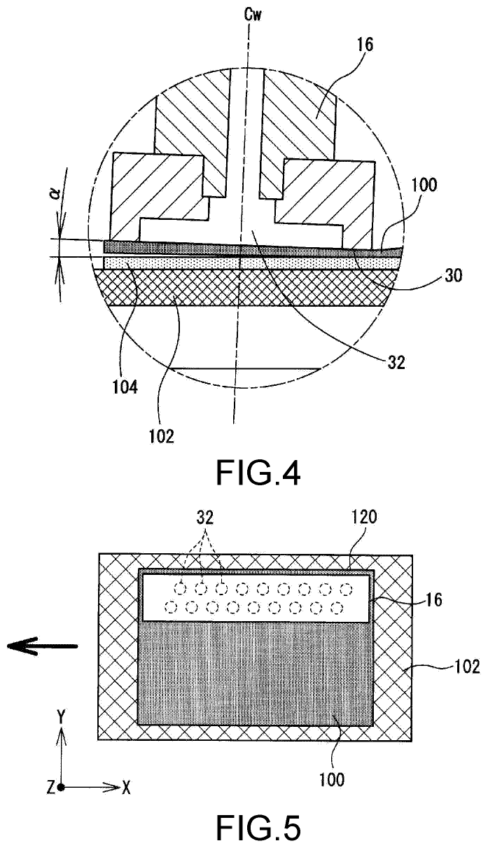

Configurations of a detachment device will be described below with reference to drawings. FIG. 1 is a schematic configuration diagram of a detachment device 10 for protective films. FIG. 2 is a schematic diagram illustrating shapes of a collet 16 and workpieces 102. In addition, FIG. 3 is a side view illustrating a state of detachment of a protective film 100, and FIG. 4 is an enlarged diagram of a part of FIG. 3.

The detachment device 10 is a device for detaching the protective film 100 from an adhesion member (a DAF 104) attached to the workpiece 102. The workpiece 102 is, for example, a semiconductor chip mounted on a substrate 110. The DAF 104 is attached to a surface of the workpiece 102 as an adhesion member. The DAF 104 is a film with the function of a die attach agent (a bonding agent) as is known, and the DAF 104 is cured by heating and bonded to a semiconductor chip. Normally, such a DAF 104 is laminated on the back surface of a semiconductor chip or attached to the substrate 110. In the present example, in order to gain a so-called package-on-package (PoP) structure in which a semiconductor chip is bonded onto an upper surface of another semiconductor chip, the DAF 104 is attached to an upper surface of a semiconductor chip (the workpiece 102) mounted on the substrate 110. An outer surface of the DAF 104 (the surface thereof that is not attached to the semiconductor chip) is an adhesive surface to which another semiconductor chip adheres. The adhesive surface of the DAF 104 is covered and protected by the protective film 100 to prevent contamination or attachment of foreign substances.

The protective film 100 is a film formed of, for example, a resin material such as PET and covers the entire adhesive surface of the DAF 104. Before the DAF 104 is used, that is, when the semiconductor chip is mounted via the DAF 104, or the like, the protective film 100 is detached from the DAF 104 beforehand. The detachment device 10 disclosed in the present specification is a device that detaches the protective film 100 protecting the surface of the DAF 104 from the DAF 104. Note that, the protective film 100 is normally thicker than the DAF 104 in most cases, and the protective film 100 has a thickness of, for example, 35 μm to 100 μm, and the DAF 104 has a thickness of 15 μm to 30 μm.

The detachment device 10 is broadly divided into a workpiece transport mechanism 14 that transports the workpiece 102 and a detachment mechanism 12 that detaches the protective film 100. The workpiece transport mechanism 14 is a mechanism that transports the workpiece 102 mounted on the substrate 110 in one direction (an X axis direction in the present example). The workpiece 102 is transported in a state in which it is placed on a transport table 22. The transport table 22 is moved by a mechanism constituted by, for example, a motor, ball screws, a slide rail, and the like in the X axis direction. Note that, a plurality of workpieces 102 are two-dimensionally arrayed on one substrate 110.

The detachment mechanism 12 has the collet 16 that sucks the protective film 100, a movement mechanism 18 that moves the collet 16 relative to the workpiece 102, a vacuum source 20 that generates suction power, and the like. The movement mechanism 18 has a plurality of motors, ball screws that convert motions of the motor into straight movements, and the like, and moves the collet 16 in three directions of the X, Y and Z axes.

The collet 16 is a member that sucks and holds the protective film 100. The bottom surface of the collet 16 functions as a contact surface 30 that comes in contact with a surface of the workpiece 102 (i.e., an outer surface of protective film 100 attached to the workpiece 102). Although a shape of the contact surface 30 is not particularly limited, it is a rectangular shape that is long in the Y axis direction (a direction orthogonal to the workpiece transport direction) as illustrated in FIG. 2 in the present example. More specifically, the width of the contact surface 30 in the Y axis direction is slightly smaller than the width of the protective film 100 in the Y axis direction, and the width of the contact surface 30 in the X axis direction is sufficiently smaller than the width of the protective film 100 in the X axis direction. Thus, the contact surface 30 is sufficiently smaller than the protective film 100.

When the protective film 100 is detached, the contact surface 30 comes in contact with a position in the protective film 100 that is deviated in the X axis direction, rather than a position at the center thereof. Specifically, the collet 16 is positioned such that one end side of the contact surface 30 in the X axis direction is in proximity to one end side of the protective film 100 in the X axis direction. As will be described in detail below, an end of the protective film 100 in the deflection direction (X axis direction) of the contact surface 30 is a detachment start end 120 at which detachment first occurs.

Here, in the present example, the central axis Cw of the collet 16 is slightly tilted from the vertical direction as illustrated in FIG. 4. As a result, the contact surface 30 is slightly tilted toward the surface of the workpiece 102 such that the inner end of the contact surface 30 is set be lower than the outer end thereof. Although the angle α formed by the contact surface 30 and the surface of the workpiece 102 is not particularly limited as long as the angle prevents a leak in suction, for example, the angle is from about 0.5 to 1 degree. The reason for the slight tilting of the contact surface 30 will be described below.

A suction hole 32 for sucking the protective film 100 is open within the contact surface 30. The suction hole 32 has a substantially rectangular shape so as to offset the external form of the contact surface 30 inward. The suction hole 32 is connected to the vacuum source 20.

Next, a workflow of detachment of the protective film 100 using the detachment device 10 will be described. When the protective film 100 is to be detached, the movement mechanism 18 is driven to position the collet 16 directly above the target protective film 100. Then, the vacuum source 20 is driven to lower the collet 16 while starting suction with the suction hole 32, and the contact surface 30 is brought in contact with a surface of the protective film 100.

FIG. 3 and FIG. 4 are diagrams illustrating the states of that time. As is apparent from FIG. 3, the contact surface 30 comes in contact with only one part adjacent to one end side of the protective film 100 (a detachment start end 120). Thus, the protective film 100 receives the load from the contact surface 30 only regionally. When the protective film 100 can be sucked by the suction hole 32, the collet 16 is lifted and thus the collet 16 is separated from the workpiece 102. Accordingly, the protective film 100 sucked by the suction hole 32 is separated and thus detached from the DAF 104. Then, the collet 16 is moved by the movement mechanism 18 to a discard position, which is not illustrated, and the sucked and held protective film 100 is discarded at the discard position.

As is apparent from the above description, the collet 16 of the present example comes in contact with the protective film 100 in a planar shape and sucks a periphery of the detachment start end 120 of the protective film 100. The reason for this configuration will be described by comparing the configuration with the prior art. Conventionally, an adhesive tape is mostly used for detachment of the protective film 100. That is, a conventional technology of detaching the protective film 100 by bringing an adhesive tape wound around a roll in contact with the protective film 100 and separating the adhesive tape from the workpiece 102 has mostly been used. However, in the case of the technology using such an adhesive tape, there is concern of the adhesive of the adhesive tape causing contamination or the like adhering to the substrate 110 or the like.

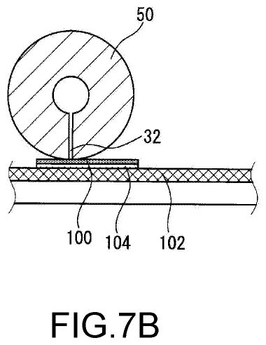

Therefore, there are some proposals for technologies of sucking and detaching such a protective film 100. FIG. 7A and FIG. 7B are diagrams illustrating an example of the prior art, and FIG. 7B is a diagram of the cross-section A-A of FIG. 7A. As illustrated in FIG. 7A and FIG. 7B, conventionally, a single suction hole 32 is provided in a roll member 50, and the roll member 50 is brought in contact with the protective film 100 in a state in which the suction hole faces downward, and then the protective film 100 is sucked. Then, after the protective film 100 is sucked, the roll member 50 is rotated to wind up the protective film 100.

In the case of the configuration in which the roll member 50 is used, however, the roll member 50 and the protective film 100 are only in linear contact. In addition, in order to prevent a leak in suction, the suction hole 32 needs to be a very small hole having a size that fits in the linear contact portion. When the suction hole 32 is small like this, there are cases in which the power of the entire roll member 50 to hold the protective film 100 tends to be small and sufficient detachment power would not be obtained.

In addition, the suction hole 32 is positioned at the linear contact portion of the roll member 50 as described above. The linear contact portion is a position at which the protective film 100 and the DAF 104 are in close contact with each other due to receiving a pressing force from the roll member 50. Since the portion at which the protective film 100 and the DAF 104 are in close contact with each other is sucked by the suction hole 32 in the prior art, it is hard to separate the protective film 100 from the DAF 104 and the protective film 100 may not be properly detached.

Meanwhile, in the present example, the contact surface 30 of the collet 16 comes in contact with the protective film 100 in a planar shape and the suction hole 32 is provided within the contact surface 30 as described above. Thus, it is possible to design a position and a shape of the suction hole 32 more freely than in the case of FIG. 7. As a result, a sufficiently high power to hold the protective film 100 can be secured.

In addition, in the present example, the contact surface 30 is set to be smaller than the protective film 100 and comes in contact with a portion adjacent to an end of the protective film 100 (the detachment start end 120). In addition, the suction hole 32 sucks the periphery of the end of the protective film 100 (the detachment start end 120). Accordingly, warping or peeling of the protective film 100 easily occurs, and thus the protective film 100 can be detached more reliably. That is, while the protective film 100 hardly peels off from the center in general, it peels off mostly from an end thereof. Therefore, it can be said that it is desirable for the suction hole 32 to suck the periphery of an end of the protective film 100, rather than the center thereof.

Furthermore, in the present example, the contact surface 30 is slightly tilted toward the surface of the workpiece 102 such that the inner end of the contact surface 30 is set to be lower than the outer end of the contact surface 30. When this configuration is employed, the protective film 100 receives a maximum force from the inner end of the contact surface 30 as illustrated in FIG. 4, and thus warps from the contact portion of the inner end of the contact surface 30. Since the suction hole 32 is positioned on an outer side from the inner end, the suction hole 32 can suck the protective film 100 that has warped and been slightly lifted. In other words, in the present example, the suction hole 32 sucks the protective film 100 from a portion slightly lifted from the DAF 104, unlike in the case of FIG. 7. As a result, the protective film 100 can peel off from the DAF 104 even when the suction power of the suction hole 32 is relatively small. Note that, the contact surface 30 is tilted in the range in which a leak during suction can be prevented. That is, when the protective film 100 receives a local load, so-called sinking in which a partial thickness of the protective film decreases occurs. The contact surface 30 is tilted in the range in which the difference in the heights of the outer end and the inner end falls into the amount of the partial sinking of the protective film 100. Accordingly, while leaks are prevented, the protective film 100 can be sucked and held more reliably, and further the protective film 100 can be detached more reliably.

Note that, the configurations described so far are all examples, and another configuration may be appropriately changed as long as the contact surface 30 that comes in contact with the protective film 100 in a planar shape and the suction hole 32 provided within the contact surface 30 are included. For example, although the suction hole 32 is set to have a substantially rectangular shape in which the contact surface 30 is offset inside in the above description, another shape is possible as long as sufficient holding power can be obtained. The suction hole 32 may be, for example, a round hole. In addition, the number of the suction holes 32 may be one or more. Thus, the suction hole 32 may be set to multiple holes arrayed in two rows as illustrated in FIG. 5. However, in order to secure stable holding power, it is desirable to arrange the suction holes 32 in a lengthwise direction along an end side that is the detachment start end 120 of the protective film 100.

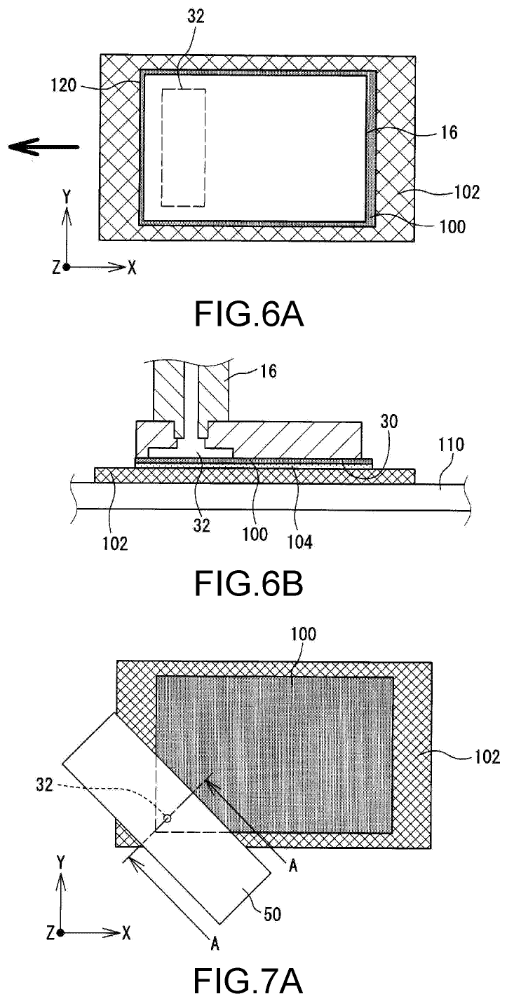

In addition, although the contact surface 30 is set to have a substantially rectangular shape smaller than the protective film 100 in the above description, a shape and a size of the contact surface 30 are not particularly limited as long as the contact surface can come in contact with the protective film 100 in a planar shape. Thus, the contact surface 30 may have a circular shape, an elliptical shape, a square shape, or the like. In addition, the contact surface 30 may have a size in which the contact surface can come in contact with nearly the entire surface of the protective film 100 as illustrated in FIG. 6A and FIG. 6B. Even when the contact surface 30 is set to have a size substantially equal to that of the protective film 100, it is desirable for the suction hole 32 to be provided at a periphery of an end of the protective film 100, rather than the center thereof. The reason for this is that the protective film 100 is easily detached when a periphery of an end thereof is sucked.

In addition, the contact surface 30 is brought in contact with the protective film 100 at a position close to an end in the X axis direction (an end in the transport direction) and the periphery of the end in the X direction is sucked by the suction hole 32 in the above description. In the case of the configuration, the end of the protective film 100 in the transport direction is the detachment start end 120. However, another part may be the detachment start end 120. For example, the end in the Y axis direction substantially orthogonal to the transport direction may be the detachment start end 120 as illustrated in FIG. 5. When the end in the direction substantially orthogonal to the transport direction is set as the detachment start end 120 as illustrated in FIG. 5, the accuracy in positioning of the detachment start end 120 increases, and thus the protective film 100 can be detached more reliably.

That is, in the case of the configuration of FIG. 2, since the detachment start end 120 is an end in the transport direction of the workpiece 102, the accuracy in a position of the detachment start end 120 heavily depends on the accuracy of transport of the workpiece 102. Meanwhile, in the case of the configuration of FIG. 5, the detachment start end 120 is an end in the Y direction substantially orthogonal to the transport direction of the workpiece 102. Since the workpiece 102 is transported while the position in the Y axis direction remains substantially fixed, the accuracy of the position in the Y axis direction may be higher than the accuracy of a position in the X axis direction, without depending on the accuracy of the transport of the workpiece 102. Thus, in the case of the configuration of FIG. 5, the accuracy in relative positioning of the collet 16 and the detachment start end 120 can be increased, and thus the protective film 100 can be detached more reliably.

In addition, the protective film 100 is separated from the workpiece 102 after the protective film is sucked by the suction hole 32 and the collet 16 is moved in the above description. However, either of the workpiece 102 and the collet 16 may be moved if the collet 16 and the workpiece 102 are relatively moved after the protective film 100 is sucked.

### REFERENCE SIGNS LIST

10 Detachment device
12 Detachment mechanism
14 Workpiece transport mechanism
16 Collet
18 Movement mechanism
20 Vacuum source
22 Transport table
30 Abutting surface
32 Absorption hole
50 Roll member
100 Protective film
102 Workpiece
104 DAF
110 Substrate
120 Detachment start end

1. A detachment device that detaches a protective film protecting a surface of an adhesion member from the adhesion member attached to a workpiece, and the detachment device comprising:
a collet, including an contact surface that comes in contact with a periphery of an end side of a surface of the protective film adhered to the adhesion member in a planar shape, and a suction hole that is provided within the contact surface and sucks the protective film; and
a movement mechanism that moves the collet with respect to the workpiece,
wherein the protective film is detached from the adhesion member by separating the collet from the workpiece in a state in which the protective film is sucked by the suction hole;
the contact surface is tilted toward a surface of the workpiece, such that an inner end of the contact surface is set to be lower than an outer end of the contact surface in a range in which a leak during a suction does not occur;
a difference in heights of the outer end and the inner end of the contact surface falls into a range of a sinking amount of the protective film.

2. (canceled)

3. (canceled)

4. The detachment device according to claim 1, wherein
an area of the contact surface is smaller than the protective film.

5. A detachment device that detaches a protective film protecting a surface of an adhesion member from the adhesion member attached to a workpiece, and the detachment device comprising:
a collet, including an contact surface that comes in contact with a surface of the protective film adhered to the adhesion member in a planar shape, and a suction hole that is provided within the contact surface and sucks the protective film; and
a movement mechanism that moves the collet with respect to the workpiece,
wherein the protective film is detached from the adhesion member by separating the collet from the workpiece in a state in which the protective film is sucked by the suction hole;
the contact surface comes in contact with a periphery of an end of the protective film and in a direction substantially orthogonal to a transport direction of the workpiece.

6. (canceled)
